(19) United States
(12) Patent Application Publication
(10) Pub. No.: US 2007/0194417 A1
(43) Pub. Date: Aug. 23, 2007

(54) Semiconductor apparatus containing multi-chip package structures

(75) Inventor: Yuichi Yoshida, Miyazuki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/638,477

(22) Filed: Dec. 14, 2006

(30) Foreign Application Priority Data
Feb. 20, 2006 (JP) 2006-42360

(51) Int. Cl. H01L 23/02

(52) U.S. Cl. 257/678

(57) ABSTRACT

The present invention is applied to a semiconductor apparatus using a lead frame as a base frame. A semiconductor apparatus according to the present invention includes a first multi-chip structure, which comprises a plurality of semiconductor chips mounted on the base frame and a terminal region formed on at least one surface of the multi-chip structure, the terminal region being connected electrically to an external component; and a second multi-chip structure, which comprises a plurality of semiconductor chips mounted on the base frame and a terminal region formed on at least one surface of the multi-chip structure, the terminal region being connected electrically to an external component. Inner leads of the base frame are connected to the terminal region of the first multi-chip structure by a wire-bonding process and to the terminal region of the second multi-chip structure by a wire-bonding process.

### CROSS REFERENCE TO RELATED APPLICATION

This application claims the priority of Application No. 2006-42360, filed on Feb. 20, 2006 in Japan, the subject matter of which is incorporated herein by reference.

### TECHNICAL FIELD OF THE INVENTION

The present invention relates to a semiconductor apparatus containing multi-chip package structures.

### BACKGROUND OF THE INVENTION

In recent years, electronic devices, including personal mobile devices, has been improved with higher operations speed and smaller size. In response to such improvement of electronic devices, a semiconductor package has been improved with larger capacity, higher operation speed and smaller size.

Recently, in order to miniaturize a semiconductor package, a BGA (Ball Grid Array) type of semiconductor package and a CSP (Chip Scale Package) type of semiconductor package are proposed and practically used instead of a pin type semiconductor package.

Further, a multi-layered type of semiconductor package has been published, for example, in U.S. Pat. No. 6,268,649, wherein packaging density is improved and multi-functions are provided. An invention described in U.S. Pat. No. 6,268,649 is applied to a structure in which plural BGA packages are layered (piled up) therein. Each of the plural BGA packages includes a substrate; a semiconductor chip, which is arranged at the center of the substrate and resin-molded; and solder balls arranged on rear surfaces of substrates, provided at both sides of the semiconductor chip. In general, for a multi-layered type of semiconductor package, the above-described structure of BGA packages are piled up one on the other using solder balls as electrical connection.

[Patent Related Publication 1] U.S. Pat. No. 6,268,649

Japanese Patent Publication No. 2005-26680A describes a multi-layered type of BGA package, wherein plural semiconductor packages, each containing a plurality of semiconductor chips, are mounted. According to the publication, the multi-layered type of BGA package includes a base package, containing a plurality of semiconductor chips; and other plural BGA packages, each containing a plurality of semiconductor chips, layered (piled up) on the base BGA package. The base BGA package and the other BGA packages, mounted on the base BGA package, are electrically connected by solder balls.

### [Patent Related Publication 1] JP Patent Publication No. 2005-26680A

However, according to the conventional structures of BGA package, described in the Patent Related Publications 1 and 2, a large amount of stress is applied to semiconductor chips and the semiconductor chips may be damaged. In addition, according to the conventional structures of BGA package, fabrication process is complicated. A process of solder ball connection is carried out for each layer, so that a reflow process, which is a kind of thermal treatment, is required for fabricating the package. Further, it is required to coat a solder paste on a circuit board as a tacking material when a BGA package is mounted on the circuit board. Therefore, it is difficult to apply such a BGA package to a small size of semiconductor apparatus. Still further, terminals are arranged with a smaller pitch and space, and therefore, it is difficult to perform a characteristic test for each semiconductor chip.

### OBJECTS OF THE INVENTION

Accordingly, a first object of the present invention is to provide a semiconductor apparatus containing multi-chip structures, in which damage to semiconductor chips can be reduced.

A second object of the present invention is to provide a semiconductor apparatus containing a multi-chip structure, which can be fabricated at a higher workability.

A third object of the present invention is to provide a semiconductor apparatus containing a multi-chip structure, in which a characteristic test can be carried out easily for each semiconductor chip.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a semiconductor apparatus using a lead frame as a base frame, comprising: a first multi-chip structure, which comprises a plurality of semiconductor chips mounted on the base frame and a terminal region formed on at least one surface of the multi-chip structure, the terminal region being connected electrically to an external component; and a second multi-chip structure, which comprises a plurality of semiconductor chips mounted on the base frame and a terminal region formed on at least one surface of the multi-chip structure, the terminal region being connected electrically to an external component. Inner leads of the base frame are connected to the terminal region of the first multi-chip structure by a wire-bonding process and to the terminal region of the second multi-chip structure by a wire-bonding process. The lead frame is used as a base frame of the semiconductor apparatus, which can be connected to external components.

According to a second aspect of the present invention, a semiconductor apparatus using a lead frame as a base frame, comprising: a first multi-chip structure, which comprises a plurality of semiconductor chips mounted on a first surface of the base frame and a terminal region formed on a surface opposing to the first surface of the multi-chip structure, the terminal region being connected electrically to an external component; and a second multi-chip structure, which comprises a plurality of semiconductor chips mounted on a second surface opposing to the first surface of the base frame and a terminal region formed on a surface opposing to the second surface of the multi-chip structure, the terminal region being connected electrically to an external component. Inner leads of the base frame are connected to the terminal region of the first multi-chip structure by a wire-bonding process and to the terminal region of the second multi-chip structure by a wire-bonding process.

### ADVANTAGES OF THE INVENTION

According to the present invention, a base frame and multi-chip structures are electrically connected by a wire-bonding process, so that stress applied to semiconductor chips can be reduced. As a result, damages to the semiconductor chips can be reduced as well.

Further, according to the present invention, it is unnecessary to perform solder-ball connection for each layer and to perform any heat treatment. As a result, workability and process efficiency for fabricating a semiconductor apparatus could be improved.

In addition, terminals can be arranged or located with a larger pitch and space, and therefore, it is easy to perform a characteristic test for each semiconductor chip.

### BRIEF DESCRIPTION OF THE DRAWINGS

FIG. 1 is a cross-sectional view illustrating a semiconductor apparatus according to a first preferred embodiment of the present invention.

FIG. 2 is a plane view illustrating a semiconductor apparatus according to the first preferred embodiment, shown in FIG. 1.

FIGS. 3A-3D are cross-sectional views illustrating fabrication steps of a semiconductor apparatus according to the first preferred embodiment, shown in FIG. 1.

FIG. 4 is a cross-sectional view illustrating a semiconductor apparatus according to a second preferred embodiment of the present invention.

FIG. 5 is a cross-sectional view illustrating a semiconductor apparatus according to a third preferred embodiment of the present invention.

FIG. 6 is a cross-sectional view illustrating a semiconductor apparatus according to a fourth preferred embodiment of the present invention.

FIG. 7 is a cross-sectional view illustrating a semiconductor apparatus according to a fifth preferred embodiment of the present invention.

### DESCRIPTION OF THE REFERENCE NUMERALS

100, 200, 300, 400 and 500: Semiconductor Apparatus
102: QFN Package
104, 106, 134, 136: Semiconductor Chip
140: Die Pad
108: Inner Lead
112, 114, 142, 148, 150 and 152: Bonding Wire

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present invention is defined only by the appended claims.

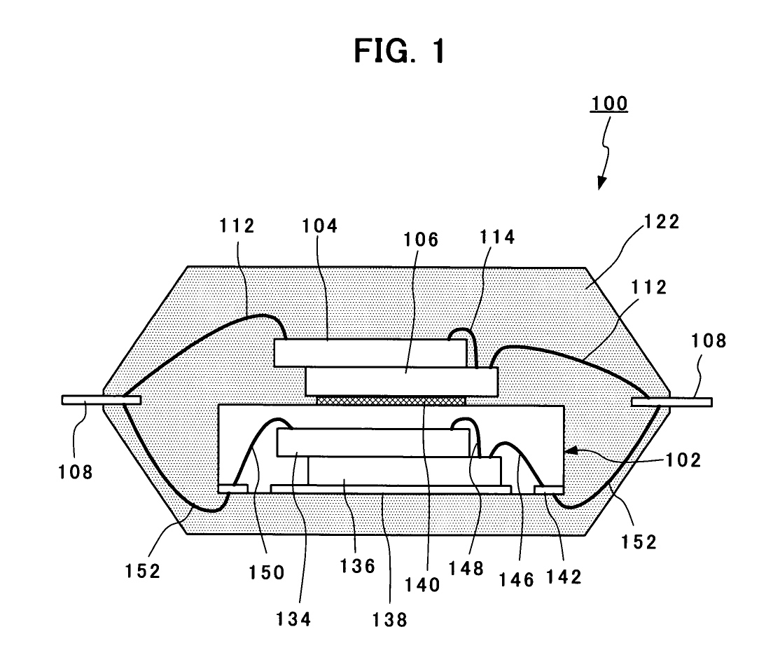

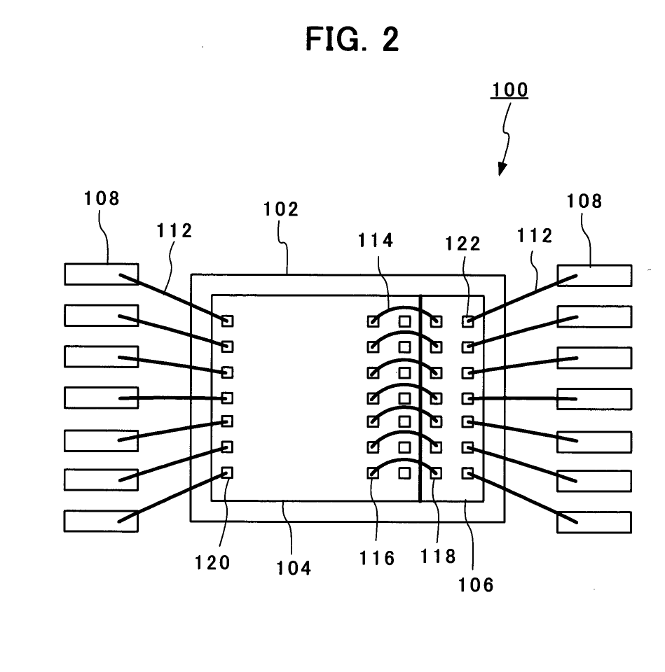

The present invention is now described with preferred embodiments as follows: FIGS. 1 and 2 are a cross-sectional view and a plan view illustrating a semiconductor apparatus 100 according to a first preferred embodiment of the present invention. A semiconductor apparatus 100 includes a lead frame having a die pad 140 and inner leads 108. The lead frame is used as a base frame of the semiconductor apparatus, which can be connected to external components. A first multi-chip structure (104, 106) is mounted on an upper surface of the die pad 140. The first multi-chip structure includes a plurality of semiconductor chips 104 and 106, which are layered (piled up one on the other) in the structure. On the other hand, a second multi-chip structure 102 is mounted on a lower or rear surface of the die pad 140. The second multi-chip structure 102 includes a plurality of semiconductor chips 134 and 136, which are layered (piled up one on the other) in the structure.

As shown in FIG. 2, in the firs multi-chip structure, the semiconductor chip 106 is mounted on the die pad 140, and the semiconductor chip 104 is mounted on the semiconductor chip 106. External-connection terminals 120 are formed on an upper surface of the semiconductor chip 104 so that the terminals 120 are connected to the inner leads 108 with bonding wires 112. Internal-connection terminals 116 are formed on the upper surface of the semiconductor chip 104 so that the terminals 116 are connected to the semiconductor chip 106 with bonding wires 114. External-connection terminals 122 are formed on an upper surface of the semiconductor chip 106 so that the terminals 122 are connected to the inner leads 108 with bonding wires 112. Internal-connection terminals 118 are formed on the upper surface of the semiconductor chip 106 so that the terminals 118 are connected to the semiconductor chip 104 with the bonding wires 114.

The semiconductor chip 104 and the semiconductor chip 106 are arranged to be offset (shifted in location) in a horizontal direction so that a wire-bonding process can be carried out easily. According to FIGS. 1 and 2, the same size of semiconductor chips 104 and 106 are employed. However, different sizes and different functions of semiconductor chips can be used. For example, the same function of memory chips could be used, or the different functions of semiconductor chips could be used.

Now referring again FIG. 1, the second multi-chip structure 102 is of a QFN (Quad Flat No-Lead) type of semiconductor package, in which semiconductor chips 134 and 136 are mounted on a lead frame (138). The semiconductor chips 134 and 136 could be arranged in the same or similar layout as the first multi-chip structure (104+106), described above. In the QFN package 102, the semiconductor chip 136 is mounted on a die pad 138, and the semiconductor chip 134 is mounted on the semiconductor chip 136. External-connection terminals are formed on an upper surface of the semiconductor chip 134 so that the external-connection terminals are connected to the inner leads 142 with bonding wires 150. Internal-connection terminals are formed on the upper surface of the semiconductor chip 134 so that the internal-connection terminals are connected to the semiconductor chip 136 with bonding wires 148.

In the QFN package 102, connection terminals are formed on the upper surface of the semiconductor chip 136, so that the connection terminals are connected to the inner leads 142 with bonding wires 146. Other connection terminals are formed on the upper surface of the semiconductor chip 136, so that the connection terminals are connected to the semiconductor chip 134 with bonding wires 148. In the QFN package 102, the inner leads 142 have exposed lower surfaces, to be connected with bonding wires 152 to inner leads 108 of the base frame. In the same manner as the first multi-chip structure (104+106), the semiconductor chip 134 and the semiconductor chip 136 are arranged to be offset (shifted in location) in a horizontal direction so that a wire-bonding process can be carried out easily.

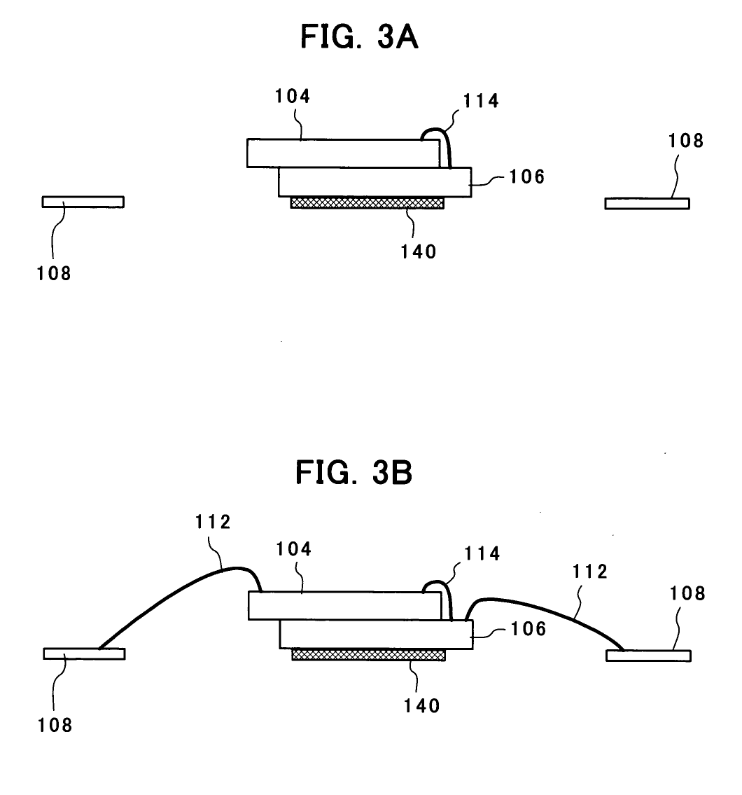

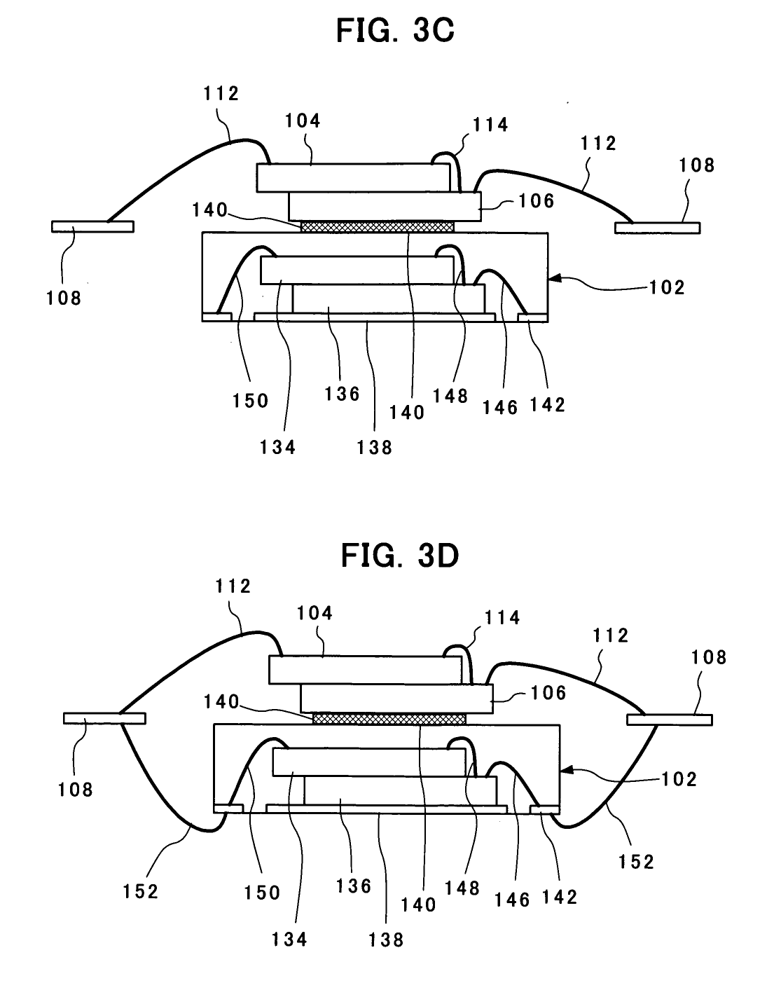

Next, fabrication steps for the semiconductor apparatus 100 according to the first preferred embodiment are described in reference to FIGS. 3A-3D. First, as shown in FIG. 3A, semiconductor chips 104 and 106 are piled up and mounted on a die pad 140 of a lead frame (base frame), and the semiconductor chips 104 and 106 are connected to each other with bonding wires 114. Next, as shown in FIG. 3B, the semiconductor chips 104 and 106 are connected to the inner leads 108 with bonding wires 112.

Subsequently, as shown in FIG. 3C, a QFN package 102, which is fabricated in advance by a well known method, is adhered on a rear surface of the die pad 140. The QFN package 102 includes a resin portion sealing the semiconductor chips 134 and 136. The resin portion has a first surface located at a side of the lead frame (138, 142) and a second surface located at the counter side of the lead frame (138, 142). In the adhering process, the second surface of the resin portion is adhered to the die pad 140. Next, as shown in FIG. 3D, the inner leads 142 of the QFN package 102 and the inner leads 108 of the base frame are connected to each other using bonding wires 152. After that, the entire structure is sealed with a resin 122, as shown in FIG. 1.

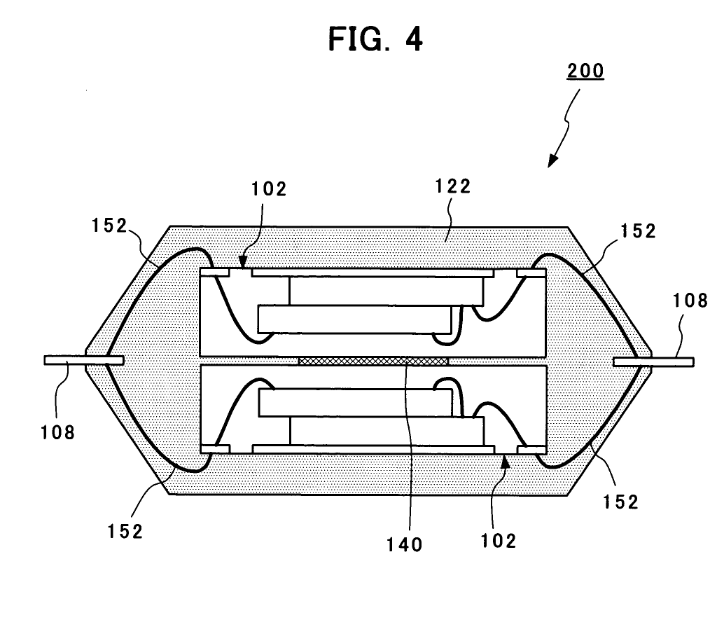

Now, second to fifth preferred embodiments of the present invention are described. In the description of the following embodiments, the same or corresponding components to those in the first preferred embodiment, shown in FIGS. 1, 2 and 3A-3D, are represented by the same reference numerals and the same description is not repeated. FIG. 4 is a cross-sectional view illustrating a semiconductor apparatus 200 according to the second preferred embodiment of the present invention. The semiconductor apparatus 200 uses a lead frame (108, 140) as a base frame. The lead frame includes a die pad 140 and inner leads 108. According to the present embodiment, two of QFN type semiconductor packages 102 are mounted on upper and lower surfaces of the die pad 140. First and second multi-chip structures 102, each containing a plurality of semiconductor chips, are mounted on upper and lower surfaces of the die pad 140.

According to the second preferred embodiment, shown in FIG. 4, QFN packages are mounted on both surfaces of the lead frame (base frame), so that mounting process can be carried out for each package (package by package) independently. As a result, handling ability during a fabrication process is improved.

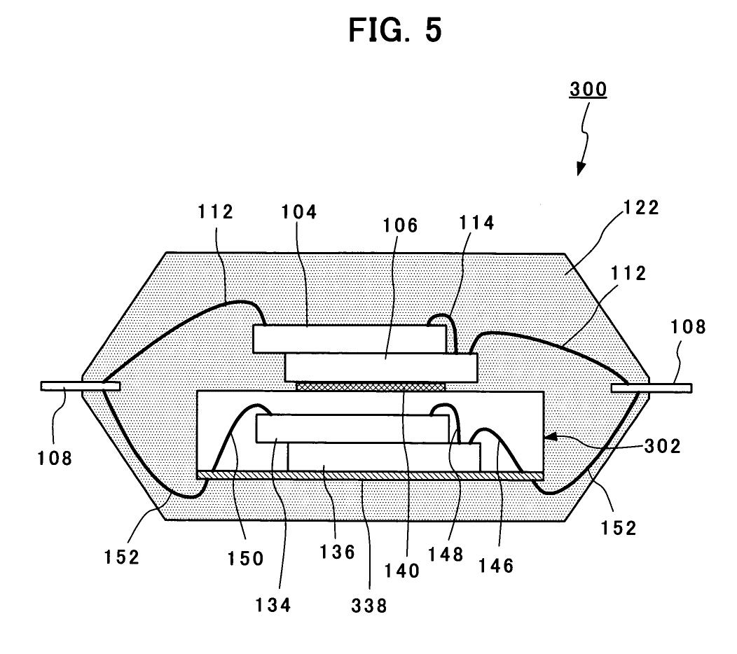

FIG. 5 is a cross-sectional view illustrating a semiconductor apparatus 300 according to the third preferred embodiment of the present invention. The semiconductor apparatus 300 uses a lead frame (108, 140) as a base frame. According to the above described first preferred embodiment, a QFN package is used as a second multi-chip structure and is mounted on a rear surface of a die pad. According to the present embodiment, LGA (Land Grid Array) type of semiconductor package 302 is used as a second multi-chip structure. In the LGA package 302, semiconductor chips 134 and 136 are piled up and mounted on a printed-circuit board 338. According to the third preferred embodiment, a freedom degree of a wiring design is increased.

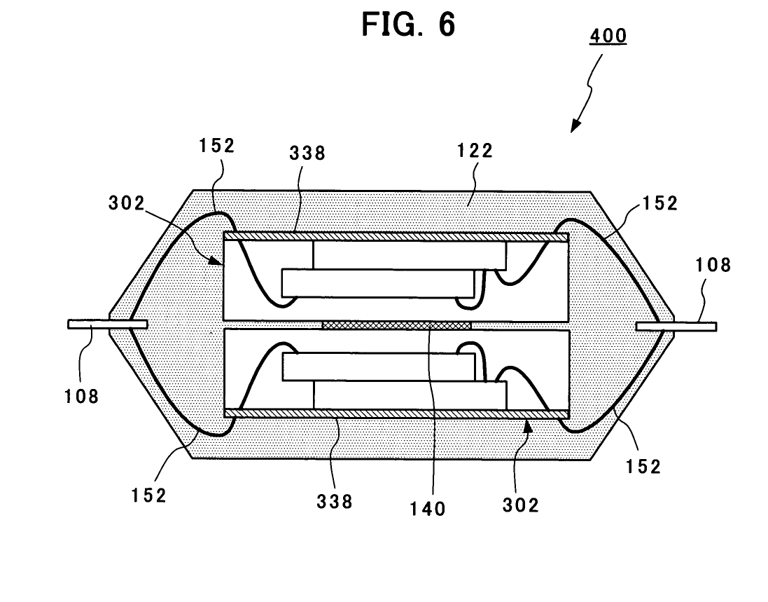

FIG. 6 is a cross-sectional view illustrating a semiconductor apparatus 400 according to the fourth preferred embodiment of the present invention. The semiconductor apparatus 400 uses a lead frame (108, 140) as a base frame. The lead frame includes a die pad 140 and inner leads 108. According to the above described third preferred embodiment, a LGA package 302 is mounted only on a rear surface of the die pad 140. According to the present embodiment, two LGA type of semiconductor packages 302 are mounted on both front and rear (upper and lower) surfaces of the die pad 140.

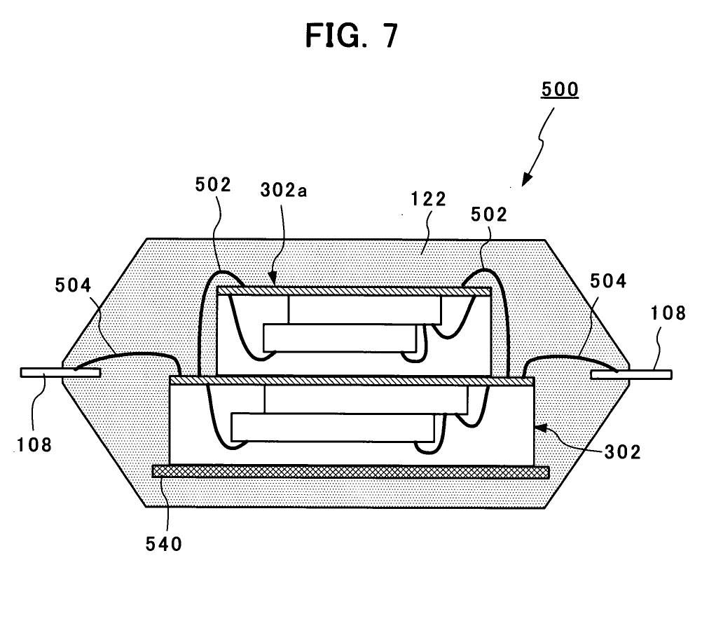

FIG. 7 is a cross-sectional view illustrating a semiconductor apparatus 500 according to the fifth preferred embodiment of the present invention. The semiconductor apparatus 500 uses a lead frame (108, 540) as a base frame. The lead frame includes a die pad 540 and inner leads 108. The die pad 540 is shaped and arranged at a lower level relative to the inner leads 108. In other words, the lead frame is shaped to have a depressed region, which is to be used for the die pad 540. A feature of the present embodiment is that different sizes of LGA packages 302 and 302a are directly piled up and mounted on the die pad 540.

The LGA package 302 is arranged to have a printed-circuit board face up and the lower surface, which is the counter side of the printed-circuit board, is in contact with an upper surface of the die pad 540. The LGA package 302a is arranged to have a printed-circuit board face up and the lower surface, which is the counter side of the printed-circuit board, is in contact with a rear surface of the printed-circuit board of the LGA package 302. The LGA packages 302 and 302a are connected with bonding wires 502 to each other. The inner leads 108 are connected to the rear surface of the printed-circuit board in the LGA package 302 with boding wires 604.

As described above, according to the fifth preferred embodiment, plural semiconductor packages of different sizes are piled up, a die pad is unnecessary to be provided between those semiconductor packages. Therefore, fabrication steps are simplified and workability is improved. Such advantages are remarkable, and such a structure is appropriate to LGA packages, having a high freedom degree of wiring design.

According to the present invention, a semiconductor package, including inner leads with exposed rear surfaces, or a LGA type package is used, a semiconductor apparatus can be fabricated using a well known wire-bonding process. Further, bonding areas are located apart from semiconductor chips, so that a stress to be applied to the semiconductor chips can be reduced in a bonding process for connecting multi-chip structures.

The present invention is not limited by the above described embodiments. For example, three or more semiconductor chips can be piled up in each multi-chip structure, and three or more semiconductor packages can be piled up in a semiconductor apparatus.

What is claimed is:

1. A semiconductor apparatus using a lead frame as a base frame, comprising:
a first multi-chip structure, which comprises a plurality of semiconductor chips mounted on the base frame and a terminal region formed on at least one surface of the multi-chip structure, wherein the terminal region can be connected electrically to an external component; and
a second multi-chip structure, which comprises a plurality of semiconductor chips mounted on the base frame and a terminal region formed on at least one surface of the multi-chip structure, wherein the terminal region can be connected electrically to an external component,
wherein inner leads of the base frame are connected to the terminal region of the first multi-chip structure by a wire-bonding process and to the terminal region of the second multi-chip structure by a wire-bonding process.

2. A semiconductor apparatus using a lead frame as a base frame, comprising:
a first multi-chip structure, which comprises a plurality of semiconductor chips mounted on a first surface of the base frame and a terminal region formed on a surface opposing to the first surface of the multi-chip structure, wherein the terminal region can be connected electrically to an external component; and
a second multi-chip structure, which comprises a plurality of semiconductor chips mounted on a second surface opposing to the first surface of the base frame and a terminal region formed on a surface opposing to the second surface of the multi-chip structure, wherein the terminal region can be connected electrically to an external component,
wherein inner leads of the base frame are connected to the terminal region of the first multi-chip structure by a wire-bonding process and to the terminal region of the second multi-chip structure by a wire-bonding process.

3. A semiconductor apparatus according to claim 2, wherein
at least one of the first multi-chip structure and the second multi-chip structure is of a QFN package, in which a plurality of semiconductor chips are layered and mounted on a lead frame.

4. A semiconductor apparatus according to claim 3, wherein
both the first multi-chip structure and the second multi-chip structure are of QFN packages,
each of the QFN packages comprises a resin portion sealing the semiconductor chips mounted on the lead frame, and
the resin portion has a first surface located at a side of the lead frame and a second surface located at the counter side of the lead frame.

5. A semiconductor apparatus according to claim 4, wherein
the second surface of the resin portion of the QFN structure for the first multi-chip structure is adhered to the first surface of the base frame; and
the second surface of the resin portion of the QFN structure for the second multi-chip structure is adhered to the second surface of the base frame.

6. A semiconductor apparatus according to claim 2, wherein
at least one of the first multi-chip structure and the second multi-chip structure is of a LGA package, in which a plurality of semiconductor chips are layered and mounted on a printed-circuit board.

7. A semiconductor apparatus according to claim 2, wherein
both the first multi-chip structure and the second multi-chip structure are LGA packages, in which a plurality of semiconductor chips are layered and mounted on a printed-circuit board,
the LGA package comprises a resin portion sealing the semiconductor chips mounted on the printed-circuit board, and
the resin portion has a first surface located at a side of the printed-circuit board and a second surface located at the counter side of the printed-circuit board.

8. A semiconductor apparatus according to claim 7, wherein
the second surface of the resin portion of the LGA package for the first multi-chip structure is adhered to the first surface of the base frame; and
the second surface of the resin portion of the LGA package for the second multi-chip structure is adhered to the second surface of the base frame.

9. A semiconductor apparatus according to claim 1, wherein
the first multi-chip structure and the second multi-chip structure are LGA packages, in which a plurality of semiconductor chips are layered and mounted on a printed-circuit board,
the first multi-chip structure is formed to be larger in size than the second multi-chip structure,
the base frame comprises a die pad, and
the first multi-chip structure is mounted on the die pad of the base frame, and the second multi-chip structure is mounted on the first multi-chip structure.

10. A semiconductor apparatus according to claim 9, wherein
the first multi-chip structure comprises a resin portion sealing the semiconductor chips, which has a first surface located at a side of the printed-circuit board and a second surface located at the counter side of the printed-circuit board to seals the semiconductor chips mounted in the structure,
the second multi-chip structure comprises a resin portion sealing the semiconductor chips, which has a first surface located at a side of the printed-circuit board and a second surface located at the counter side of the printed-circuit board to seals the semiconductor chips mounted in the structure,
the second surface of the resin portion of the first multi-chip structure is adhered to the die pad of the base frame,
the second surface of the resin portion of the second multi-chip structure is adhered to a rear surface of the printed circuit board of the first multi-chip structure,
rear surfaces of the printed-circuit boards of the first and second multi-chip structures are electrically connected to each other using bonding wires, and
the rear surface of the printed-circuit board of the first multi-chip structure is electrically connected to the inner leads of the base frame using bonding wires.

11. A semiconductor apparatus according to claim 1, wherein
the plural semiconductor chips are arranged to be offset in a horizontal direction from each other, and
the connection between every semiconductor ships is carried out by a wire-bonding process.

12. A semiconductor apparatus according to claim 2, wherein
the plural semiconductor chips are arranged to be offset in a horizontal direction from each other, and
the connection between every semiconductor ships is carried out by a wire-bonding process.

13. A semiconductor apparatus according to claim 1, further comprising:
a seal resin which seals the first and second multi-chip structures entirely.

14. A semiconductor apparatus according to claim 2, further comprising:
a seal resin which seals the first and second multi-chip structures entirely.
